(19) United States
(12) Patent Application Publication
(10) Pub. No.: US 2021/0394331 A1
(43) Pub. Date: Dec. 23, 2021

(54) SEMICONDUCTOR SUBSTRATE POLISHING WITH POLISHING PAD TEMPERATURE CONTROL

(71) Applicant: GlobalWafers Co., Ltd., Hsinchu (TW)

(72) Inventor: Masaaki Ikeda, Utsunomiya City (JP)

(21) Appl. No.: 16/946,340

(22) Filed: Jun. 17, 2020

(51) Int. Cl. B24B 37/015; B24B 37/20; B24B 49/14

(52) U.S. Cl. CPC B24B 37/015; B24B 49/14; B24B 37/20

(57) ABSTRACT

A method of preheating a polishing pad of a semiconductor wafer polishing system includes heating a fluid to a first predetermined temperature. The method also includes applying the fluid to the polishing pad. The method further includes rotating the polishing pad such that the fluid covers the polishing pad. The fluid increases a polishing pad temperature to a second predetermined temperature.

### FIELD

The field of the disclosure relates to polishing semiconductor substrates and, in particular, methods and systems that involve controlling a temperature of a polishing pad.

### BACKGROUND

Semiconductor wafers are commonly used in the production of integrated circuit (IC) chips on which circuitry are printed. The circuitry is first printed in miniaturized form onto surfaces of the wafers. The wafers are then broken into circuit chips. This miniaturized circuitry requires that front and back surfaces of each wafer be extremely flat and parallel to ensure that the circuitry can be properly printed over the entire surface of the wafer. To accomplish this, polishing processes are commonly used to improve flatness and parallelism of the front and back surfaces of the wafer after the wafer is cut from an ingot. A particularly good finish is required when polishing the wafer in preparation for printing the miniaturized circuits on the wafer by an electron beam-lithographic or photolithographic process (hereinafter “lithography”). The wafer surface on which the miniaturized circuits are to be printed must be flat.

Double side polishing may include simultaneously polishing the front and back surfaces of the wafers. Specifically, an upper polishing pad polishes a top surface of the wafer while a lower polishing pad simultaneously polishes a bottom surface of the wafer. However, the polishing process may cause the profile of the semiconductor wafer to be uneven because of inconsistent polishing pad temperatures throughout the polishing process. For example, changes in polishing pad temperature through the polishing process may vary the shape of the polishing pad and may vary the profile of the wafer.

There is a need for methods and systems for polishing semiconductor substrates that provide a consistent polishing pad temperature throughout the polishing process.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method of preheating a polishing pad of a semiconductor wafer polishing system. The method includes heating a fluid to a first predetermined temperature. The method also includes applying the fluid to the polishing pad. The method further includes rotating the polishing pad such that the fluid covers the polishing pad. The fluid increases a polishing pad temperature to a second predetermined temperature.

Another aspect of the present disclosure is directed to a method of polishing a semiconductor wafer with a wafer polishing system. The wafer polishing system includes a preheating system and a polishing head. The preheating system includes a heater, and the polishing head includes a polishing pad. The method includes heating a fluid to a first predetermined temperature with the heater. The method also includes applying the fluid to the polishing pad. The method further includes rotating the polishing pad such that the fluid covers the polishing pad. The fluid increases a polishing pad temperature to a second predetermined temperature. The method also includes placing the wafer in the wafer polishing system. The method further includes polishing the wafer with the polishing pad.

Yet another aspect of the present disclosure is directed to a wafer polishing system for polishing a semiconductor wafer. The wafer polishing system includes a polishing head including a polishing pad and a preheating system for preheating the polishing pad. The preheating system includes a heater for heating a fluid to a first predetermined temperature. The preheating system channels the fluid to the polishing pad, and the fluid raises a polishing pad temperature to a second predetermined temperature.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic of a wafer polishing system.

FIG. 2 is a flow diagram of a method of preheating a polishing head.

FIG. 3 is a flow diagram of a method of polishing a wafer.

FIG. 4 is a graph of the change in the temperature of the polishing pad when varying the duration of a preheating process of the polishing pad.

FIG. 5 is a box-plot of the change in TAPER of finish polished wafers when varying the duration of a preheating process of the polishing pad.

Although specific features of various examples may be shown in some drawings and not in others, this is for convenience only. Any feature of any drawing may be referenced and/or claimed in combination with any feature of any other drawing.

Unless otherwise indicated, the drawings are meant to illustrate features of examples of the disclosure. These features are believed to be applicable in a variety of systems comprising one or more examples of the disclosure. The drawings are not meant to include all conventional features known by those of ordinary skill in the art to be required for the practice of the disclosed examples disclosed.

### DETAILED DESCRIPTION

Suitable substrates (which may be referred to as semiconductor or silicon “wafers”) include single crystal silicon substrates including substrates obtained by slicing the wafers from ingots formed by the Czochralski process. Each substrate includes a central axis, a front surface, and a back surface parallel to the front surface. The front and back surfaces are generally perpendicular to the central axis. A circumferential edge joins the front and back surfaces.

In one example, a preheating step increases a temperature of a polishing pad to a predetermined temperature. In this example, deionized (“DI”) water is heated and then the DI water is applied to the polishing pad, and the polishing pad is rotated so that the temperature of the polishing pad becomes substantially uniform. The DI water increases the temperature of the polishing pad, and the heated polishing pad is used to polish a semiconductor wafer. Increasing the temperature of the polishing pad prior to polishing the wafer increases the temperature of the polishing pad to a temperature less than or approximately equal to the temperature of the polishing pad during polishing of the wafer. After the polishing pad has been preheated, one or more polishing steps are performed in which the front surface and/or the back surface of the structure are polished (i.e., a single or double-side polish is performed).

Preheating the polishing pad results in more consistent polishing pad temperature during the polishing process. A consistent polishing pad temperature during the polishing process results in more uniform silicon removal during the polishing process. Polishing pad temperature is increased by frictional forces at a wafer-polishing pad interface during a chemical-mechanical polishing process. The preheating process increases the polishing pad temperature prior to the polishing process such that the polishing pad temperature is consistent throughout the polishing process and the removal profile of the wafer is uniform.

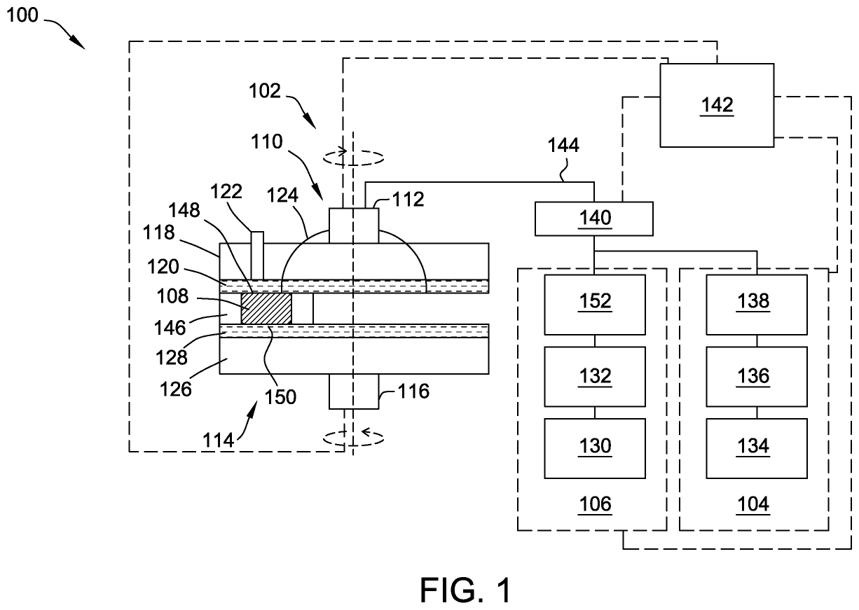

With reference to FIG. 1, a wafer polishing system 100 includes a polisher 102, a preheating system 104, and a slurry supply system 106. The polisher 102 polishes a wafer 108, and the slurry supply system 106 provides a slurry to the polisher during the polishing process. The preheating system 104 preheats the polisher 102 prior to the polishing process in order to increase a temperature of the polisher to a temperature less than or approximately equal to a polishing temperature of the polisher during the polishing process.

The polisher 102 includes a first polishing head (upper polishing head) 110 attached to a first shaft 112 and a second polishing head (lower polishing head) 114 attached to a second shaft 116. The first shaft 112 rotates the first polishing head 110, and the second shaft 116 rotates the second polishing head 114. The first polishing head 110 includes a first plate (upper plate) 118 and a first polishing pad (upper polishing pad) 120 attached to the first plate. The first polishing head 110 also includes a polishing pad temperature sensor 122 and a plurality of fluid distribution tubes 124. The polishing pad temperature sensor 122 measures the temperature of the first polishing pad 120 and a second polishing pad 128, and the fluid distribution tubes 124 apply a first fluid to the first polishing pad and the second polishing pad. In the illustrated embodiment, the polishing pad temperature sensor 122 is a resistance temperature detector. However, the polishing pad temperature sensor 122 may be any type of temperature sensor that enables the polisher 102 to operate as described herein. Similarly, the second polishing head 114 includes a second plate (lower plate) 126 and a second polishing pad (lower polishing pad) 128 attached to the second plate.

The polisher 102 is a double-side polisher that rough or finish polishes the wafer 108. The rough and finish polish may be achieved by, for example, chemical-mechanical planarization (CMP). CMP typically involves the immersion of the wafer 108 in an abrasive slurry supplied by the slurry supply system 106 and polishing the wafer by the first and second polishing pads 120 and 128. Through a combination of chemical and mechanical action the surface of the wafer 108 is smoothed. Typically the polish is performed until a chemical and thermal steady state is achieved and until the wafers 108 have achieved their targeted shape and flatness.

The preheating system 104 includes a preheating tank 134, a preheating pump 136, a preheating flow controller 138, and a heater 140. The preheating tank 134 contains the first fluid, and the preheating pump 136 pumps the first fluid from the tank to the preheating flow controller 138, the heater 140, and the first polishing head 110. The preheating flow controller 138 controls the flow of the first fluid from the preheating pump 136, and the heater 140 increases a temperature of the first fluid prior to sending the first fluid to the first and second polishing heads 110 and 114.

The preheating tank 134 includes a nonmetallic tank that contains the first fluid. For example, in this embodiment, the preheating tank 134 includes a polytetrafluoroethylene (PTFE) tank. In alternative embodiments, the preheating tank 134 includes any type of tank, including a metallic tank, that enables the preheating system 104 to operate as described herein. The preheating pump 136 includes any pump suitable for pumping the first fluid from the preheating tank 134 to the first polishing head 110, including, but not limited to, a centrifugal pump, a positive displacement pump, and/or any other fluid motive device. The preheating flow controller 138 includes any flow control device that controls the flow of the first fluid. The heater 140 includes any heating device that increases the temperature of the first fluid including, but not limited to, an electric heater, a gas heater, a heat exchanger, and/or any other heating device.

In this embodiment, the first fluid includes deionized water. More specifically, the first fluid includes a non-abrasive fluid, such as deionized water, that is substantially free of silicon dioxide. In alternative embodiments, the first fluid may include any fluid that enables the preheating system 104 and the polisher 102 to operate as described herein.

The slurry supply system 106 includes a slurry tank 130, a slurry pump 132, a slurry flow controller 152, and the heater 140. The slurry tank 130 contains a second fluid, and the slurry pump 132 pumps the second fluid from the slurry tank to the slurry flow controller 152, the heater 140, and the first polishing head 110. The slurry flow controller 152 controls the flow of the second fluid from the slurry pump 132, and the heater 140 increases a temperature of the second fluid prior to sending the second fluid to the first polishing head 110.

The slurry tank 130 includes a nonmetallic tank that contains the second fluid. For example, in this embodiment, the slurry tank 130 includes a PTFE tank. In alternative embodiments, the slurry tank 130 includes any type of tank, including a metallic tank, that enables the slurry supply system 106 to operate as described herein. The slurry pump 132 includes any pump suitable for pumping the second fluid from the slurry tank 130 to the first polishing head 110, including, but not limited to, a centrifugal pump, a positive displacement pump, and/or any other fluid motive device. The slurry flow controller 152 includes any flow control device that controls the flow of the second fluid. The slurry supply system 106 uses the same heater 140 as the preheating system 104 to increase the temperature of the second fluid.

The slurry supply system 106 provides the second fluid to the polisher during the polishing process. In this embodiment, the second fluid is a slurry. In alternative embodiments, the second fluid may include any fluid that enables the polisher 102 to operate as described herein. For example, suitable slurries that may be used alone or in combination in the polishing process include a first polishing slurry comprising an amount of silica particles, a second polishing slurry that is alkaline (i.e., caustic) and typically does not contain silica particles, and a third polishing slurry that is deionized water. In this regard, it should be noted that the term “slurry” as referenced herein denotes various suspensions and solutions (including solutions without particles therein such as caustic solution and deionized water) and is not intended to imply the presence of particles in the liquid. The silica particles of the first slurry may be colloidal silica and the particles may be encapsulated in a polymer.

The wafer polishing system 100 may also include a controller 142 that controls the polisher 102, the preheating system 104, and the slurry supply system 106. For example, the controller 142 may control the rotational speed of the polisher 102, the flow rate of the first fluid, the temperature of the first fluid, and/or the duration of preheating.

During operation, the preheating system 104 preheats the polisher 102, and the polisher polishes the wafer 108 after the temperatures of the first and second polishing pads 120 and 128 have been increased. Specifically, the polishing process begins by pumping the first fluid from the preheating tank 134 to the preheating flow controller 138 and the heater 140 with the preheating pump 136. The preheating flow controller 138 controls the flow of the first fluid, and the heater 140 increases a temperature of the first fluid to a first predetermined temperature. In this example, the first predetermined temperature is about 20° C. In alternative examples, the first predetermined temperature may be any temperature that enables the preheating system 104 to operate as described herein.

The heated first fluid is channeled to a conduit 144 at least partially within the first shaft 112. The conduit 144 channels the first fluid to the fluid distribution tubes 124, which, in turn, apply the heated first fluid to the first and second polishing pads 120 and 128. The first fluid falls onto the second polishing pad 128, increasing the temperature of the second polishing pad. The first and second shafts 112 and 116 simultaneously rotate the first and second polishing heads 110 and 114 to coat the first fluid on the first and second polishing pads 120 and 128. The first fluid increases the temperature of the first and second polishing pads 120 and 128 to a second predetermined temperature. The first fluid is applied to the first and second polishing pads 120 and 128 for a predetermined time such that the first fluid preheats the first and second polishing pads 120 and 128 for the predetermined time. In this embodiment, the predetermined time is about 8 minutes. In alternative embodiments, the predetermined time is any amount of time that enables polisher 102 to operate as described herein.

Alternatively, the second polishing head 114 may also include fluid distribution tubes that channel the first fluid to the second polishing head 114 while simultaneously channeling the first fluid to the first polishing head 110. Additionally, the second polishing head 114 may also include a polishing pad temperature sensor that measures a temperature of the second polishing pad 128.

The first predetermined temperature is based on the second predetermined temperature, and the second predetermined temperature is based on the polishing temperature. Specifically, the polishing temperature is determined by a chemical and thermal steady state that is achieved when the wafers 108 have achieved their targeted shape and flatness. The thermal steady state determines the polishing temperature. In this example, the polishing pad temperature is maintained within ±0.4° C. of the polishing temperature, and the first and second predetermined temperatures are selected such that the polishing pad temperature is maintained within ±0.4° C. of the polishing temperature. In this embodiment, the polishing temperature is about 42° C. to about 43° C. More specifically, in this embodiment, the polishing temperature is about 42.5° C. In alternative embodiments, the polishing temperature may be any temperature that enables the polisher 102 to operate as described herein.

The second predetermined temperature is less than or approximately equals the polishing temperature. More specifically, the second predetermined temperature is about 42° C. to about 43° C. More specifically, in this embodiment, the second predetermined temperature is about 42.5° C.

The first predetermined temperature is calculated based on the second predetermined temperature. Specifically, the first predetermined temperature is set such that the polishing pad temperature is increased to less than or approximately equal to the second predetermined temperature during the preheating process. A lower first predetermined temperature increases the duration of preheating, and a higher first predetermined temperature decreases the duration of preheating. In this embodiment, the first predetermined temperature is about 20° C. In another embodiment, the first predetermined temperature is about 20° C. to about 45° C., about 40° C. to about 45° C., about 42° C. to about 43° C., or about 42.5° C.

The polishing pad temperature sensor 122 measures a measured temperature of the first and second polishing pads 120 and 128 during the preheating process and sends the measured temperature to the controller 142. The controller 142 controls the polisher 102 and the preheating system 104 based on the measured temperature. Specifically, the controller 142 may control the rotational speed of the polisher 102, the flow rate of the first fluid, the temperature of the first fluid, and/or the duration of preheating. For example, the controller 142 may vary a flow rate of the first fluid using the preheating flow controller 138 based on the measured temperature, vary the temperature of the first fluid using the heater 140 based on the measured temperature, vary the predetermined time based on the measured temperature, and/or vary a rotational speed of the polisher 102 based on the measured temperature. Varying the operational parameters listed above enables the controller 142 to control the polishing pad temperature such that the polishing pad temperature is stable at the second predetermined temperature prior to polishing with the polisher 102. For example, as shown below in Example 1, increasing the predetermined time results in a more consistent polishing pad temperature. Additionally, increasing the flow rate of the first fluid may reduce the predetermined time, and simultaneously increasing the first temperature and the flow rate of the first fluid may further reduce the predetermined time.

Preheating the first and second polishing pads 120 and 128 increases the temperature of the polishing pads to the second predetermined temperature before polishing the wafer 108 with the polisher 102. Inconsistent temperatures during the polishing process may vary a shape of the first and second polishing pads 120 and 128, and, in turn, may vary the removal profile on the wafer 108. Consistent polishing pad temperature results in uniform silicon removal during the polishing process and is affected by the supply of the second fluid.

In contrast, in conventional methods of polishing a wafer, the polisher is idle prior to the polishing process and the polishing pad temperature at the beginning of the polishing process is typically less than a thermal steady state temperature achieved during the polishing process. The polishing pad temperature is increased by frictional forces at a wafer-polishing pad interface in the chemical-mechanical polishing process. The polishing pad temperature then increases throughout the polishing process and is time dependent and inconsistent throughout the polishing process. Inconsistent polishing pad temperature impacts the wafer flatness or TAPER. The preheating system 104 described herein increases the polishing pad temperature prior to the polishing process such that the polishing pad temperature is consistent throughout the polishing process and the removal profile of the wafer is uniform.

After the polisher 102 has been preheated, the wafer 108 is positioned in a carrier 146, and the wafer and the carrier are positioned within the polisher 102. The second fluid (or slurry) is channeled to the polisher 102, and a first polishing step is performed in which a front surface 148 and a back surface 150 of the wafer 108 are polished by double-side polishing. Specifically, the second fluid is pumped from the slurry tank 130 to the slurry flow controller 152 and the heater 140 with the slurry pump 132. The slurry flow controller 152 controls the flow of the second fluid, and, in some examples, the heater 140 may increase a temperature of the second fluid. The second fluid is channeled to the conduit 144 at least partially within the first shaft 112. The conduit 144 channels the second fluid to the fluid distribution tubes 124, which, in turn, apply the second fluid to the first and second polishing pads 120 and 128. The second fluid falls onto the second polishing pad 128. The first and second shafts 112 and 116 simultaneously rotate the first and second polishing heads 110 and 114 to coat the second fluid on the first and second polishing pads 120 and 128 and polish the wafer 108.

Friction between the first and second polishing pads 120 and 128, the wafer 108, and the slurry maintains the polishing pad temperature at the second predetermined temperature during the polishing process. Specifically, in this embodiment, friction between the first and second polishing pads 120 and 128, the wafer 108, and the slurry maintains the polishing pad temperature between 42° C. and 43° C. during the polishing process. Generally, the polish is a “rough” polish that reduces the TAPER of the wafer 108 to less than about 60 nanometers (nm) to even as low as about 5 nm or even about 1 nm. For purposes of this specification, TAPER is expressed as the linear component of the variation in thickness across a wafer, indicated by the angle between the best fit plane to the front surface and the ideally flat back surface of the wafer as defined in the American Society for Testing and Materials (“ASTM”) F1241 standard.

After the rough polish is complete, the wafers 108 may be rinsed and dried. In addition, the wafers 108 may be subjected to a wet bench or spin cleaning. After cleaning, a second polishing step may be performed. The second polishing step is typically a “finish” or “mirror” polish in which the front surface of the substrate is contacted with a polishing pad attached to a turntable or platen. Alternatively, the polisher 102 may perform the second polishing step. The finish polish reduces the TAPER of the wafer 108 to less than about 60 nanometers (nm) to even as low as about 5 nm or even about 1 nm.

As compared to conventional methods for polishing substrates, methods of the present disclosure have several advantages. Preheating the polishing pads prior to polishing a wafer increases the polishing pad temperature to a thermal steady state temperature achieved during the polishing process. Friction between the wafer, the polishing pad, and the slurry maintains the polishing pad temperature at a consistent temperature during the polishing process. The consistent polishing pad temperature during the polishing process results in reduced TAPER of the wafer and uniform silicon removal during the polishing process.

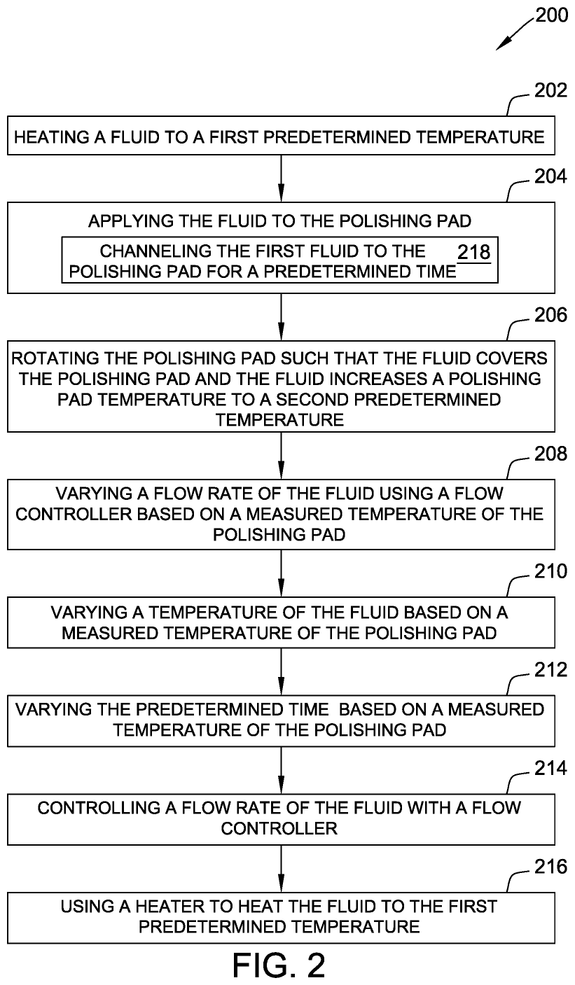

FIG. 2 is a flow diagram of a method 200 of preheating a polishing head of a semiconductor wafer polishing system. The method 200 includes heating 202 a fluid to a first predetermined temperature and applying 204 the fluid to the polishing pad. The method 200 also includes rotating 206 the polishing pad such that the fluid covers the polishing pad and the fluid increases a polishing pad temperature to a second predetermined temperature. The method 200 may also include varying 208 a flow rate of the fluid using a flow controller based on a measured temperature of the polishing pad; varying 210 a temperature of the fluid based on a measured temperature of the polishing pad; varying 212 the predetermined time based on a measured temperature of the polishing pad; controlling 214 a flow rate of the fluid with a flow controller; and using 216 a heater to heat the fluid to the first predetermined temperature. Additionally, applying 204 the fluid to the polishing pad may also include channeling 218 the first fluid to the polishing pad for a predetermined time.

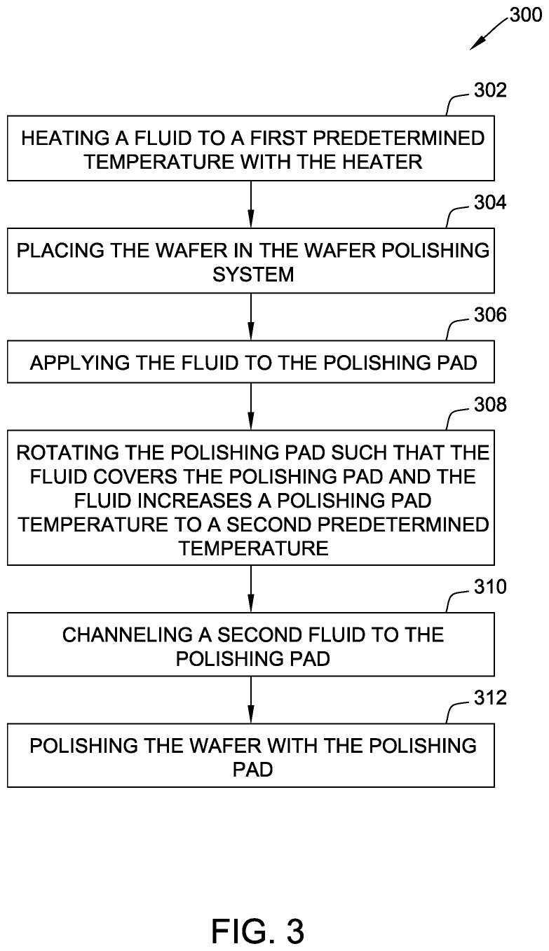

FIG. 3 is a method 300 of polishing a semiconductor wafer with a wafer polishing system. The wafer polishing system includes a preheating system and a polishing head, the preheating system includes a heater, and the polishing head includes a polishing pad. The method 300 includes heating 302 a fluid to a first predetermined temperature with the heater and placing 304 the wafer in the wafer polishing system. The method 300 also includes applying 306 the fluid to the polishing pad and rotating 308 the polishing pad such that the fluid covers the polishing pad and the fluid increases a polishing pad temperature to a second predetermined temperature. The method 300 further includes channeling 310 a second fluid to the polishing pad and polishing 312 the wafer with the polishing pad.

### EXAMPLES

The processes of the present disclosure are further illustrated by the following Examples. These Examples should not be viewed in a limiting sense.

### Example 1: Effect of Varying the Duration of Preheating on the Flatness or TAPER of a Wafer

Wafers were rough polished in a double-side polisher. Specifically, as shown in Table 1 below, three test runs were performed. In the first test run (Test Run 1), 1.3 liters per minute (1/m) of DI water at 20° C. were channeled to two polishing pads for 8 minutes prior to polishing a wafer with the polishing pads. In the second test run (Test Run 2), 1.3 l/m of DI water at 20° C. were channeled to the polishing pads for 4 minutes prior to polishing a wafer with the polishing pads. In the third test run (Test Run 3), the polishing pads were not preheated prior to polishing.

TABLE 1
Preheating Polishing Pads Test Runs 1-3

| | Test Run 1 | Test Run 2 | Test Run 3 |
|---|---|---|---|
| Time (mins) | 8 | 4 | 0 |
| DIW flow rate (Liter/min) | 1.3 | 1.3 | 1.3 |
| DIW temperature (° C.) | 20 | 20 | 20 |

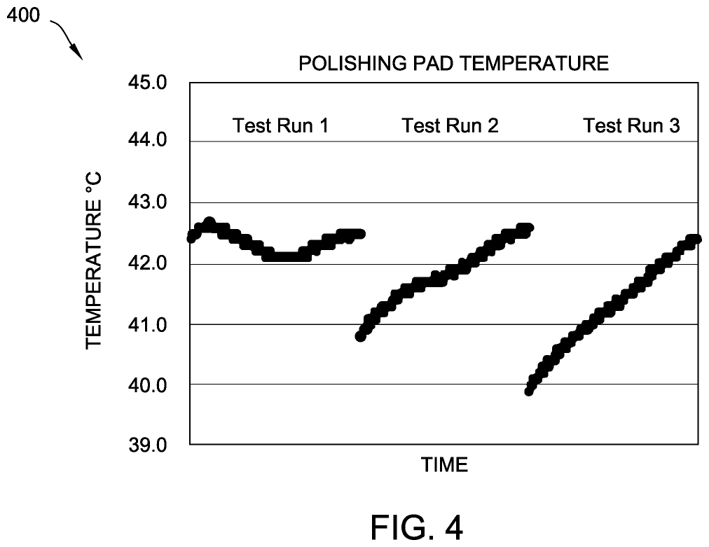

FIG. 4 is a graph 400 of the change in a temperature of a polishing pad during a polishing process when varying the duration of a preheating process of the polishing pad. As shown in FIG. 4, the temperature of the polishing pad during Test Run 1 is maintained between 42° C. and 43° C. while the temperature of the polishing pad during Test Run 2 varies between 40° C. and 43° C. and the temperature of the polishing pad during Test Run 3 varies between 39° C. and 43° C. Accordingly, a longer duration of preheating stabilizes the polishing pad temperature during the polishing process such that the polishing pad temperature is consistent throughout the polishing process. Conversely, no preheating or a shorter duration of preheating results in inconsistent polishing pad temperatures throughout the polishing process.

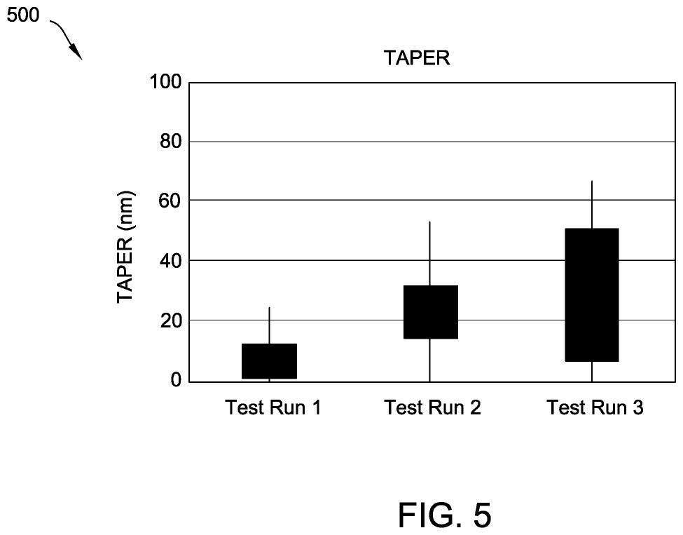

FIG. 5 is a box-plot 500 of the change in TAPER of polished wafers when varying the duration of a preheating process of a polishing pad. As shown in FIG. 5, the TAPER of the wafer produced during Test Run 1 is between about 0 nanometers (nm) and 15 nm while the TAPER of the wafer produced during Test Run 2 is between about 15 nm and 30 nm and the TAPER of the wafer produced during Test Run 3 is between about 10 nm and 50 nm. Accordingly, a longer duration of preheating reduces the TAPER and increases the flatness of the polished wafers.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method of preheating a polishing pad of a semiconductor wafer polishing system, the method comprising:
heating a fluid to a first predetermined temperature;
applying the fluid to the polishing pad; and
rotating the polishing pad such that the fluid covers the polishing pad, wherein the fluid increases a polishing pad temperature to a second predetermined temperature.

2. The method of claim 1, wherein the first predetermined temperature is calculated based on the second predetermined temperature and the polishing pad temperature.

3. The method of claim 1, wherein the polishing pad temperature is maintained between 42° C. and 43° C.

4. The method of claim 1, wherein applying the fluid to the polishing pad includes channeling the first fluid to the polishing pad for a predetermined time.

5. The method of claim 4, further comprising varying the predetermined time based on a measured temperature of the polishing pad.

6. The method of claim 1, wherein the fluid includes deionized water.

7. The method of claim 1, wherein the fluid is substantially free of silicon dioxide.

8. The method of claim 1, further comprising controlling a flow rate of the fluid with a flow controller.

9. The method of claim 1, further comprising using a heater to heat the fluid to the first predetermined temperature.

10. The method of claim 1, further comprising varying a flow rate of the fluid using a flow controller based on a measured temperature of the polishing pad.

11. The method of claim 1, further comprising varying a temperature of the fluid based on a measured temperature of the polishing pad.

12. A method of polishing a semiconductor wafer with a wafer polishing system, the wafer polishing system including a preheating system and a polishing head, the preheating system including a heater, the polishing head including a polishing pad, the method comprising:
heating a fluid to a first predetermined temperature with the heater;
applying the fluid to the polishing pad;
rotating the polishing pad such that the fluid covers the polishing pad, wherein the fluid increases a polishing pad temperature to a second predetermined temperature;
placing the wafer in the wafer polishing system; and
polishing the wafer with the polishing pad.

13. The method of claim 12, further comprising channeling a second fluid to the polishing pad.

14. The method of claim 13, wherein the second fluid comprises a slurry.

15. The method of claim 14, wherein friction between the polishing pad, the wafer, and the slurry maintains the polishing pad temperature at the second predetermined temperature.

16. A wafer polishing system for polishing a semiconductor wafer, the wafer polishing system comprising:
a polishing head comprising a polishing pad; and
a preheating system for preheating the polishing pad, the preheating system comprising a heater for heating a fluid to a first predetermined temperature, wherein the preheating system channels the fluid to the polishing pad, and the fluid raises a polishing pad temperature to a second predetermined temperature.

17. The wafer polishing system of claim 16, wherein the first predetermined temperature is calculated based on the second predetermined temperature and the polishing pad temperature.

18. The wafer polishing system of claim 16, wherein the polishing head comprises a plate attached to the polishing pad, the plate defines a fluid distribution tube for channeling the fluid from the preheating system to the polishing pad.

19. The wafer polishing system of claim 16, wherein the preheating system further comprises a polishing pad temperature sensor for measuring a polishing pad temperature.

20. The wafer polishing system of claim 16, wherein the preheating system further comprises a flow controller for controlling a flow rate of the fluid.
